(19) United States
(12) Patent Application Publication
(10) Pub. No.: US 2008/0115822 A1
(43) Pub. Date: May 22, 2008

(54) Cable Connectors for a Photovoltaic Module and Method of Installing

(75) Inventors: Daniel W. Cunningham, Mount Airy, MD (US); George J. Kelly, Mount Airy, MD (US); Dinesh S. Amin, Clarksburg, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 11/939,034

(22) Filed: Nov. 13, 2007

Related U.S. Application Data
(60) Provisional application No. 60/866,720, filed on Nov. 21, 2006.

(51) Int. Cl. H01L 31/042

(52) U.S. Cl. 136/244; 439/884

(57) ABSTRACT

A photovoltaic module having reliable connections between internal electrical terminals and output cables. The module is comprised of a backing sheet and a cover transparent sheet with a bus bar positioned therebetween. A plurality of photovoltaic (PV) cells are connected in series which, in turn, are connected to a positive and a negative terminal on the bus bar. Male connectors are connected to the positive and the negative terminals. The components are then laminated to form the module with the male connectors inside the backing sheet. To expose the male connectors, openings are formed through the backing sheet and the tapered ends of the male connectors are bent outward to be mated with female connectors on the respective cables. The connections are then soldered to provide output connections for the module.

This application claims the benefit of U.S. Provisional Patent Application 60/866,720, filed on Nov. 21, 2006.

### FIELD OF THE INVENTION

The present invention relates to photovoltaic module and connectors for attaching cables to its output terminals and in one of its aspects relates to highly reliable connectors for connecting output cables to the electrical terminals of a photovoltaic module and a method for installing the connectors.

### BACKGROUND OF THE INVENTION

In recent years, considerable advances have been made in photovoltaic (PV) cells or the like for directly converting solar energy into useful electrical energy. Typically, a plurality of these photovoltaic cells are encased between a transparent sheet (e.g. glass, plastic, etc.) and a sheet of backing material, to thereby form a flat, typically rectangular-shaped solar module (sometimes called “laminate”) of a manageable size (e.g. 1 meter by 2 meters). The PV cells may be made from wafers of silicon or other suitable semiconductor material, or they can be a thin film type of cell typically deposited on the substrate or backing sheet by various processes well known in the solar module art. This is the type of solar module that can be installed onto the roof of an existing structure (e.g. a house, building, or the like) to provide all or at least a portion of the electrical energy used by that structure.

Each solar module may contain any number of individual PV cells (e.g. from 1 to about 50 or more), each of which has a positive and a negative output which, in turn, are electrically connected in series to respective terminals on a common positive and negative bus bar, as will be understood in the art. These positive and negative terminals typically may pass directly through the backing material or as preferred, may be connected through a PC board within the solar module (e.g. a PC board having components which allow the module to continue to function when one or more individual PV cells become inoperable for any reason).

Once the positive and negative terminals are provided through the backing material, they are typically connected to respective positive and negative output power cables which, in turn, convey the electric current from the module to its designated source. Typically, in known module construction, one end of each of the cables is soldered to its respective terminal on the outside of the module. Unfortunately, however, these directly soldered connections have proved unreliable in some applications and have failed during the operational life of the module due to initial poor contact between the cable and its terminal during soldering or due to wear-and-tear during operation. When poor contact between the cable and the terminal occurs, it can lead to early field failures and module damage due to overheating or the like.

Since solar energy is relatively new in a highly competitive industry, it is vital that the solar modules, themselves, be as problem-free as possible in order to make them commercially-attractive when competing with the more conventional energy sources. Accordingly, providing essentially problem-free connections between the output terminals of the module and their respective power cables which are highly reliable over the projected life of the module is an important consideration in the marketing of solar modules. The present invention provides such connections for solar modules.

### SUMMARY OF THE INVENTION

The present invention provides a photovoltaic module and a reliable and durable connection for electrically connecting the terminals within the module to power cables which, in turn, conduct the current from the module to the designated utility source.

More specifically, the module is comprised of a backing sheet and a cover transparent sheet (e.g. glass). One or more bus bars are positioned between said backing sheet and said cover sheet and has a plurality of photovoltaic (PV) cells, which are electrically connected, electrically connected to a positive terminal and a negative terminal, respectively, on the one or more bus bars. In accordance with the present invention, a first positive connection element is electrically connected to the positive terminal and a first negative connection element is electrically connected to said negative terminal.

Preferably, these connector elements are identical male connectors which have one end tapered to mate with a female connector on a respective power cable. The other end has one or more legs thereon which mate with one or more openings through the bus bar at the respective positive and negative terminals. Once the legs on the male connectors are in their respective openings in the bus bar, they are soldered to assure a reliable connection therebetween. Each connector element is suitably scored with a groove to allow ease of subsequent bending. Once the connector elements are soldered, it is preferable to cover them with a protective covering, e.g. tape, to prevent contamination during lamination of the module. The components are then laminated to form the photovoltaic module.

Once the module is laminated, openings are formed through the backing sheet at points adjacent to the, preferably male, connector elements. The backing material is cleared from these openings and the protective layer is removed from the tapered ends of the connector elements. Next, the tapered ends are bent outward so that they extend through their respective openings in the backing material and are readily exposed for connection with the preferably female connector elements which are electrically connected to the respective power cables. Once the male and female connector elements are mated, the connections are soldered to thereby provide highly reliable and durable connection between the terminals within the module and the output power cable which are necessary to utilize the power generated by the module.

### BRIEF DESCRIPTION OF THE DRAWINGS

The actual construction operation, and apparent advantages of the present invention will be better understood by referring to the drawings, not necessarily to scale, in which like numerals identify like parts and in which:

FIG. 1 is a perspective view of a photovoltaic module of the type in which the present invention can be incorporated;

FIG. 2 is a view of the underside of the bus bar of FIG. 1 before the male connectors are installed;

FIG. 3 is an enlarged view, taken with the dotted lines 3-3 of FIG. 2;

FIG. 4 is a view of the underside of the bus bar of FIG. 1 with the male connectors installed;

FIG. 5 is an enlarged view, taken with the dotted lines 5-5 of FIG. 4;

FIG. 6 is an enlarged perspective view of one of the male connectors of FIGS. 4 and 5; and

FIGS. 7A-7D illustrate the steps in installing and assembling the connectors of the present invention.

While the invention will be described in connection with its preferred embodiments, it will be understood that this invention is not limited thereto. On the contrary, the invention is intended to cover all alternatives, modifications, and equivalents that may be included within the spirit and scope of the invention, as defined by the appended claims.

### DETAILED DESCRIPTION OF THE INVENTION

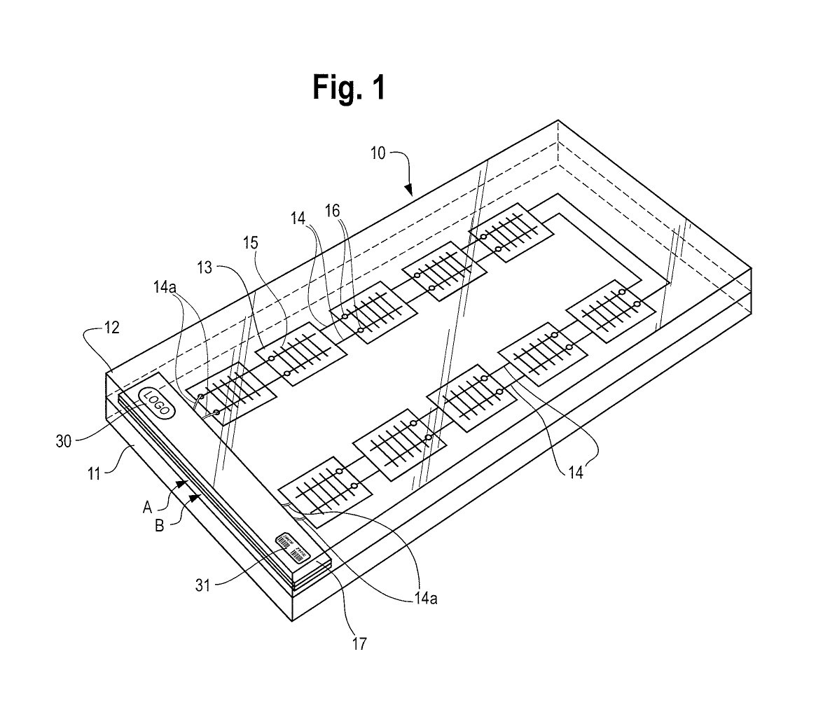

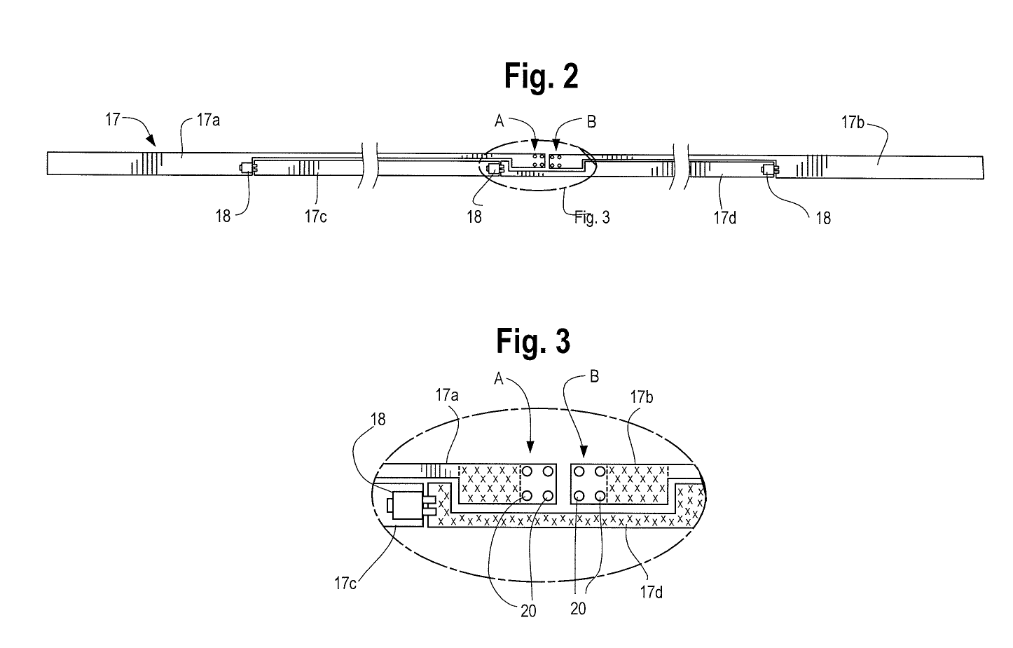

Referring now to drawings, FIG. 1 illustrates a typical photovoltaic module 10 in which the connections of the present invention can be used. Module 10 is formed of a backing sheet 11 of any suitable material, e.g. a polymeric material, and a cover substrate 12, preferably comprised of glass or other suitable transparent material. Between substrate 12 and backing sheet 11 is sandwiched a plurality of photovoltaic (PV) cells 13 (only one numbered for clarity), electrically connected in series by flat conductive ribbons or wires 14. The PV cells may be of any type such as those made from multi-crystalline or mono-crystalline silicon wafers. As shown, each cell 13 has a grid-type, front electrical contact 15 (only one numbered for clarity)

Sunlight enters through substrate sheet 12 and impinges on the front side of the PV cells 13. Each ribbon 14, which connects adjacent cells 13 in series, is connected to a contact on the back side (not shown) of one cell and to a solder contact point 16 on the front side of an adjacent PV cell 13 to couple the cells in series. Ribbons 14a connect the end cell of each row to a thin, electrically-conductive board (i.e. bus bar 17). The terms “board” and “bus bar” will be used interchangeably herein.

While board 17 may be constructed of any electrically conductive material, e.g. copper, aluminum, tin, silver, gold, etc., it is preferably formed of a laminate made by adhering a layer of conductive material to a dielectric substrate material such as a resin or polymeric material. This is the same type of material as that used to manufacture printed circuits, or so-called PC boards. Board 17 is placed between the back substrate 11 and a superstrate or cover sheet 12 and is about the same width and thickness as that of the PV cells so that when the module is laminated, it will have a substantially flat and uniform appearance.

As shown, board or bus bar 17 is comprised of four sections 17a, 17b, 17c, and 17d which form individual and separate, electrically-conducting regions on the board. While four sections are shown, it should be understood that a board 17 for a particular module may be comprised of more or less conducting regions depending, for example, on the number of rows of PV cells, number of positive and negative sites needed to provide connection points for ribbons 14a, etc. without departing from the present invention. The individual sections of board 17 are electrically connected together by respective diodes 18, preferably Schottky-type diodes. The diodes are normally in a reverse biased state when the forward-biased PV cells are all functioning to generate electrical current from solar radiation.

However, when a particular PV cell(s) malfunctions for any reason (e.g. shaded from the sun) causing it to become reverse biased, the diode in that cell's circuit also switches and becomes forward biased to prevent damage to the malfunctioning cell(s). Once the malfunction is corrected, the affected cell(s) will again become forward biased thereby causing the affected diode to become reverse biased whereupon normal operation will resume. For a more complete and detailed description of both the construction and operation of this type of board, see International Publication No. WO 2005/101511, which is incorporated herein in its entirety, by reference. Further, while only one bus bar 17 is illustrated, it should be recognized that more than one bus bar can be used if the situation dictates.

The conducting sections and diodes of board 17 act as a bus bar to conduct the electric current generated by all of the functioning cells 13 to points A and B on sections 17a and 17b, respectively. Points A and B are effectively the positive and negative terminal points for the electrical output from module 10. In order to conduct the electrical current from the module to its designated utility source (not shown), these terminal points are electrically connected to typical power cables outside the module. The present invention provides highly reliable connectors for achieving this end.

To assemble the connectors of the present invention, one or more openings 20 are formed through bus bar 17 at both points A and B. While four openings 20 are shown at each point A and B (only some numbered for clarity), it should be understood that more or less can be used as long as the number of openings correspond to the number of “legs” 21 on male connector elements 22 (see FIG. 5), as will be explained further below. The male connector elements may be comprised of any good electrically conductive material (e.g. copper, aluminum, etc.) and those used for both the positive terminal and the negative terminal are basically identical.

While the male connector elements may be structurally interchangeable, it is preferred that they be marked either “+” or “−” (see FIG. 5) to aid in connecting the proper terminals to their respective power cables after lamination, as will be fully described below. As shown, the integral, elongated body of male connector element 22 has one end 22a which is tapered for mating with a female connector element (described below) and a second end 22b which includes means for mounting the connector element 22 to bus bar 17. For a purpose described later, male connector element 22 is suitably scored with groove 22c between the respective ends.

The wall of each opening 20 is plated suitably throughout to insure good electric conductivity between the bus bar 17 and the legs of male connector element 22 when the connectors are assembled. To prevent electrical shorting between the individual components of bus bar 17, as will be understood in the art, both the cover and the underside of bus bar 17 are “masked” at points A and B and surrounding areas (see x-shaded area on FIG. 3) to prevent solder from flowing between the components of bus bar 17 during assembly of the connectors.

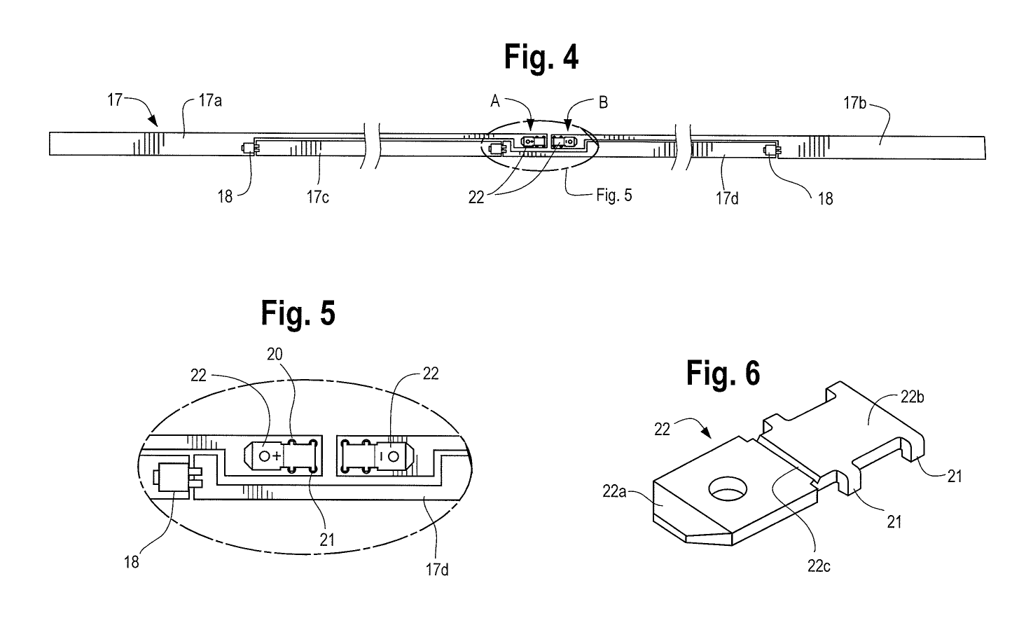

To assemble the connectors, the legs 21 of male connector elements 22 are positioned into their respective openings 20 from the underside of bus bar 17 (FIGS. 4 and 5) and are soldered in place. At this time, each of the male connector elements 20 are unbent and will lie substantially parallel to the bottoms of the bus bar 17 and the PV cells 13 so the components of the module will lie substantially flat when assembled for lamination. To protect the male connector elements from contamination during lamination of the module, each connector element is covered with a protective layer, e.g. polyester tape.

Module 10 is assembled and laminated in accordance with known procedures in the art. For example, cover sheet 12 (e.g. glass) is laid on a flat surface and a layer of EVA (ethylene vinyl acetate)/glass mat is positioned onto the cover sheet 12. Next, the rows of PV cells 13, electrically connected (e.g. in series), and the attached bus bar(s) 17 are positioned onto the EVA/glass mat with the male connectors 22 facing upward towards the backing sheet 11. Another layer of EVA/glass mat is laid thereon and the backing sheet 11 completes the assembly. This sandwich-package is then subjected to heat and pressure to form the laminated module 10, as will be understood in the art. If desired, a logo 30 and/or a Serial No. 31 (FIG. 1) or some other information can be applied directly to the top of bus bar 17 or a strip of tape including this information can be applied along the top of bar 17 before lamination. This information will be clearly visible when viewing the module and presents a clean and appealing appearance in addition to being functional.

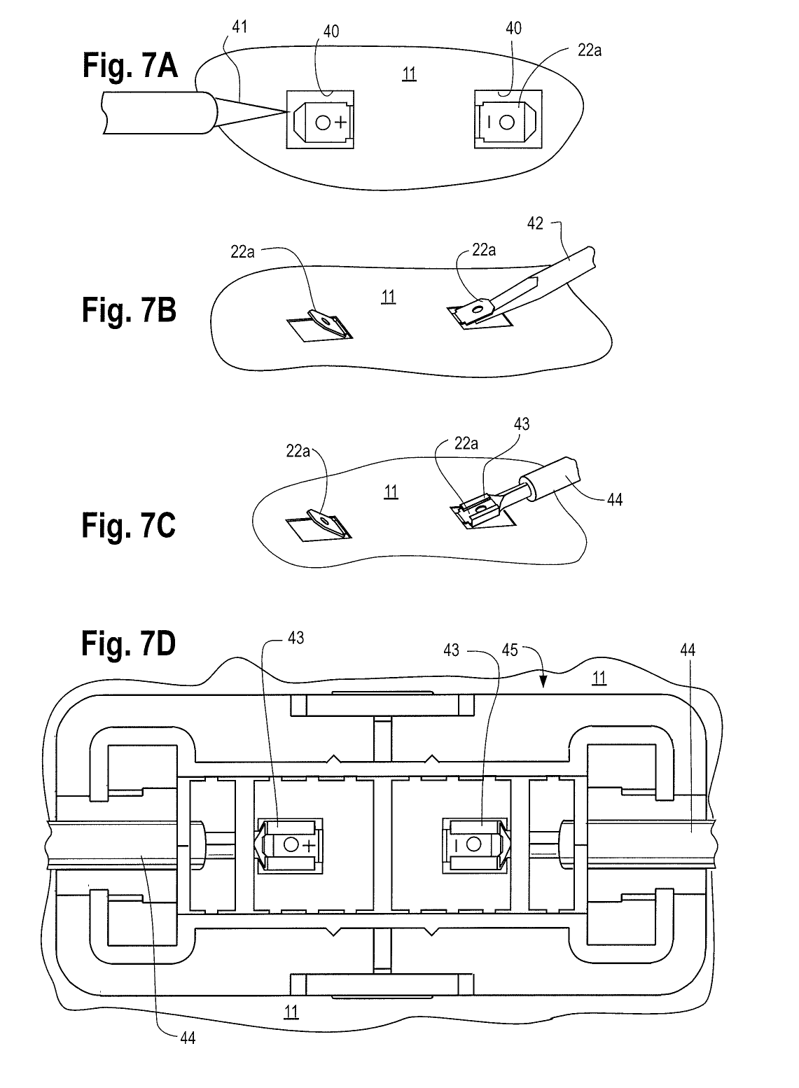

To complete the connections between the terminals A and B of the module and their respective power cables 44, reference will now be had to FIGS. 7A-7D. Once the module has been laminated, small, individual holes 40 are formed through the bottom of backing 11 to expose each of the male connector elements 22. The backing material is cleared from each of the holes 40, e.g. with a hot iron 41 (FIG. 7A) or the like. The tapered ends 22a of each male connector element are also cleared of any tape that may be used to protect these elements during lamination. Next, a screw-driver 42 or the like is inserted into the respective holes 40 and pushed under the tapered end of each male connector element 22 to bend the tapered end 22a upward to clear its hole 40 and extend it out of the backing material 11, as shown in FIG. 7B. The proper bending of each male connector element is significantly aided by a groove 22c which scores the male connector elements between their respective loose tapered ends 22a and their fixed mounting ends 22b (see FIG. 6).

With tapered ends 22a extended, a respective female element 43 which has been electrically connected (e.g. crimped and soldered) to the end of power output cable 44 is slipped over the tapered end 22a of its respective male connector element 22 and is soldered thereto to insure a secure connection therebetween (FIG. 7C). It should be recognized that, though it is preferred that the male connector elements be affixed to the bus bar 17 and the female connector elements 43 be affixed to the cables 44, their positions could be reversed without departing from the present invention. As a final step, a junction box 45 is installed over both the connections to protect them from most adverse conditions. While the actual construction of the junction box 45 may vary without departing from the present invention, preferably a junction box such as fully disclosed in WO 2006/086588 A1 (published 17 Aug. 2006 and incorporated herein in its entirety by reference) is used.

It is to be understood that only certain embodiments of the invention have been described and set forth herein. Alternative embodiments and various modifications will be apparent from the above description to those of skill in the art. These and other alternatives are considered equivalents and within the spirit and scope of the invention.

U.S. Provisional Patent Application 60/866,720, filed on Nov. 21, 2006, is incorporated herein by reference in its entirety.

What is claimed is:

1. A connection for electrically connecting the positive and negative terminals of a photovoltaic module to respective outlet cables wherein said module is comprised of a cover sheet of transparent material, at least one bus bar, a positive terminal on a bus bar and a negative terminal on a bus bar, a plurality of PV cells electrically connected to said one or more bus bars, and a backing material, all of which have been laminated into an integral module, said connection comprising:
a first positive connector element electrically connected to said positive terminal on a bus bar and extending through said backing material;
a first negative connector element electrically connected to said negative terminal on a bus bar and extending through said backing material;
a first power cable having a second positive connector element affixed thereto which mates with said first positive connector element to form an electrical connection between said first power cable and said positive terminal; and
a second power cable having a second negative connector element affixed thereto which mates with said first negative connector element to form an electrical connection between said second power cable and said negative terminal.

2. The connection of claim 1 wherein said first positive connector element and said first negative connector element comprise:
male connectors; and
wherein said second positive connector element and said second negative connector element comprise:
female connectors.

3. The connection of claim 2 wherein said first positive connector element and said second positive element are soldered together after said elements are mated; and said first negative connector element and said second negative element are soldered together after said elements are mated.

4. The connection of claim 2 wherein said first and said second male connectors are substantially identical and each comprises:
an elongated body; one end being tapered for mating with said female connector and the other end having means for mounting said body to a bus bar.

5. The connection of claim 4 wherein said elongated body includes a groove at a point between its respective ends to aid in bending said elongated body at said point.

6. The connection of claim 5 wherein said one or more bus bars include:
at least one opening therethrough at a positive terminal and at a negative terminal, respectively;
and wherein said means for mounting said body of respective said male connector elements to said bus bar at their respective terminals comprises:
at least one leg on said other end of said body, said at least one leg being positioned within said at least one opening at its respective terminal.

7. The connection of claim 6 wherein said leg of said body is soldered in its respective opening on said bus bar.

8. The connection of claim 7 wherein said at least one opening in said bus bar at each of said terminals comprises:
a plurality of openings;
and wherein said at least one leg on said male connector element comprises:
a plurality of legs equal to said plurality of openings in said bus bar.

9. The connection of claim 8 wherein the wall of each of said plurality of opening is plated throughout to insure good electric conductivity between said bus bar and said legs of male connector element 22.

10. A photovoltaic module comprising:
a backing sheet;
a cover transparent sheet;
a bus bar positioned between said backing sheet and said cover sheet, said bus bar having a positive terminal and a negative terminal;
a plurality of photovoltaic (PV) cells positioned between said backing sheet and said cover sheet, said PV cells electrically connected in series and electrically connected to said positive terminal and said negative terminal, respectively, on said bus bar;
a first positive connection element electrically connected to said positive terminal on said bus bar and extending through said backing sheet;
a first negative connection element electrically connected to said negative terminal on said bus bar and extending through said backing sheet;
a first power cable having a second positive connection element electrically affixed thereto, said second positive connection element receiving said first positive connection element to form an electrical connection therebetween; and
a second power cable having a second negative connection element electrically affixed thereto, said second negative connection element receiving said first negative connection element to form an electrical connection therebetween.

11. The photovoltaic module of claim 11 wherein said electric connections between said first and second positive connector elements and between said first and second negative connector elements are soldered.

12. The photovoltaic module of claim 11 wherein said first positive connector element and said first negative connector element comprise:
a male connector;
and wherein said second positive connector element and said second negative connector element comprise:
a female connector.

13. A method of assembling a photovoltaic module comprising:
electrically connecting a first positive connection element to a positive terminal on a bus bar and a first negative connection element to a negative terminal on said bus bar;
connecting a plurality of serially-connected PV cells to said positive and negative terminals, respectively, on said bus bar;
positioning said bus bar and connected PV cells between a backing sheet and a transparent cover sheet;
laminating said backing sheet, said cover sheet, and said bus bar and connected PV cells to form said module;
providing openings in said backing sheet adjacent said first positive connector element and said first negative connector element, respectively; and
bending said first positive connector element and said first negative connector element whereby said elements extend through their respective openings in said backing sheet.

14. A method of claim 14 wherein said first positive and said first negative connector elements are male connectors.

15. The method of claim 15 including:
applying a protective layer over said male connectors before laminating the module.

16. The method of claim 16 wherein said protective layer is removed from said male connectors when said openings are formed through said backing sheet.
